(19) United States
(12) Patent Application Publication
(10) Pub. No.: US 2011/0018123 A1
(43) Pub. Date: Jan. 27, 2011

(54) Semiconductor package and method of manufacturing the same

(75) Inventors: Jin Yong An, Yongin-si (KR); Chang Sup Ryu, Yongin-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/591,313

(22) Filed: Nov. 16, 2009

(30) Foreign Application Priority Data
Jul. 23, 2009 (KR) 10-2009-0067512

(51) Int. Cl. H01L 23/48; H01L 21/50; H01L 23/36

(52) U.S. Cl. 257/693; 438/122; 257/713; 257/723; 257/E21.499; 257/E23.051; 257/E23.101

(57) ABSTRACT

The present invention relates to a semiconductor package and a method of manufacturing the same. The semiconductor package may include: an insulator that has first and second opening parts; an active element that is disposed inside the first opening part; a passive element that is disposed inside the second opening part; a protective member that is disposed at a lower part of the insulator and covers a lower part of the passive element; a build-up layer that is disposed on the insulator and electrically connected to the active element; and an external connection unit that is electrically connected to the build-up layer.

### CROSS REFERENCES RELATED APPLICATIONS

The present application claims priority under 35 U.S.C. 119 and 35 U.S.C. 365 to Korean Patent Application No. 10-2009-0067512 filed on Jul. 23, 2009, which is hereby incorporated by reference in its entirety.

### BACKGROUND OF THE INVENTION

1. Field of the Invention

The present invention relates to a semiconductor package and a method of manufacturing the same, and more specifically, to a coreless semiconductor package and a method of manufacturing the same.

2. Description of the Related Art

Currently, as electronics are tending toward miniaturization and lightweight, parts of semiconductor devices provided in the electronics are also tending toward miniaturization and thinness. In order to meet the current technology tendency, a technology of a semiconductor package that mounts semiconductor devices on a package substrate is getting more and more attention.

The semiconductor package may include a package substrate, a semiconductor chip that is mounted on an upper surface of the package substrate by a bump ball, a molding member that seals the semiconductor chip, and a solder ball that is disposed on a lower surface of the package substrate and electrically connects the semiconductor chip with an external circuit unit, for example, a main board substrate.

Currently, as electronic equipments are tending toward high performance and miniaturization, the number of semiconductor chips has increased. Therefore, the circuit complexity and density of the package substrate have increased as well as a demand for a miniaturizing circuit has increased.

As a result, the package substrate includes circuit layers of a multi-layer that are disposed on both surfaces based on a core layer. As such, when the package substrate includes the circuit layer of a multi-layer, wiring density can increase.

However, since the circuit layers of a multi-layer on the package substrate are formed on both surfaces of the thick core layer, respectively, by a buildup scheme, there are problems in that the thickness of the package substrate can be thicker and thus, a signal transmission speed between the semiconductor chip and the external circuit unit is degraded.

Further, deformation, such as the bending of the package substrate can occur during a process of forming the circuit layer of a multi-layer. Since the problem of the bending of the package substrate can cause a bonding default between the semiconductor chip and the package substrate or a bonding fault between the package substrate and the main board substrate, it becomes a factor of degrading the reliability and productivity of the semiconductor package.

### SUMMARY OF THE INVENTION

Therefore, the present invention proposes to solve the problems that can occur in the semiconductor package of the related art. It is an object of the present invention to provide a coreless semiconductor package and a method of manufacturing the same.

It is an object of the present invention to provide a semiconductor package. The semiconductor package may include: insulators that have first and second opening parts; an active element that is disposed inside the first opening part; a passive element that is disposed inside the second opening part; a protective member that is disposed on a lower part of the insulator and covers a lower part of the passive element; a buildup layer that is disposed on the insulator and is electrically connected to the active element; and an external connection unit that is electrically connected to the buildup layer.

Herein, the protective member may cover a lower surface of the active element.

Further, the protective member may include a penetration part is disposed to correspond to the first opening part and expose the lower surface of the active element.

In addition, the semiconductor package may further include a heat dissipation member that is attached to the lower surface of the active element.

Also, the semiconductor package may further include the heat dissipation member that is disposed on the lower surface of the protective member including the lower surface of the active element.

Moreover, an etching surface of the protective member for forming the penetration part may face a side surface of the active element.

In addition, the lower surface of the insulator and the lower surface of the active element may be disposed on a straight line.

In addition, the buildup layer may be formed in a multi-layer and vias, which are provided on each buildup layer and perform interlayer connection, may be stacked in a row.

It is another object of the present invention to provide a method of manufacturing a semiconductor package. The method of manufacturing the semiconductor package may include: providing a carrier substrate; stacking insulators including first and second opening parts on both surfaces of the carrier substrate, respectively; forming each of the semiconductor packages that include active elements disposed on both surfaces of the carrier substrate corresponding to the first opening part, passive elements disposed on both surfaces of the carrier substrate corresponding to the second opening part, and a buildup layer of at least one layer electrically connected to the active element; forming a protective member, which separates the semiconductor package from the carrier substrate, on a lower part of the semiconductor package including the passive element; and forming an external connection unit on the semiconductor package.

Herein, the carrier substrate may include a supporting layer, release layers disposed on both surfaces of the supporting layer, respectively, and adhesive layers disposed on the release layers.

In addition, the forming the protective member, which separates the semiconductor package from the carrier substrate, on the lower part of the semiconductor package including the passive element may include removing the adhesive layer that is separated from the release layer and is disposed on the lower surface of the semiconductor package; and forming a protective member on the lower surface of the semiconductor package.

In addition, the forming the protective member on the lower part of the semiconductor package that separates the semiconductor package from the carrier substrate and includes the passive element can be used as a protective member by leaving the adhesive layer that is separated from the release layer and is disposed on the lower surface of the semiconductor package.

Also, the adhesive layer may include a metal thin film or an insulating film.

Moreover, the method of manufacturing the semiconductor package may further include a penetration part that exposes the lower surface of the active element.

Moreover, the method of manufacturing the semiconductor package may further include attaching a heat dissipation member to the lower surface of the active element.

Further, the buildup layer may be formed in a multi-layer and vias, which are provided on each buildup layer and perform interlayer connection, may be formed to be stacked in a row.

In addition, the forming the semiconductor packages on both surfaces of the carrier substrate, respectively, may further include forming a solder resist layer on the buildup layer.

It is still another object of the present invention to provide a method of manufacturing a semiconductor package. The method of manufacturing the semiconductor package may include: providing a carrier substrate; forming a protective member, which includes a penetration part, and insulators, which are disposed on the protective member and include first and second opening parts, on both surfaces of the carrier substrate; forming each of the semiconductor packages that includes active elements disposed on both surfaces of the carrier substrate corresponding to the first opening part, passive elements disposed on both surfaces of the carrier substrate corresponding to the second opening part, and a buildup layer of at least one layer electrically connected to the active element; separating the semiconductor package including the protective member from the carrier substrate; and forming an external connection unit on the semiconductor package.

Herein, the forming the insulator and the protective member may include forming the protective members including the penetration parts on both surfaces of the carrier substrate, respectively; and stacking insulators including the first opening part corresponding to the penetration part and the second opening part disposed around the first opening part on the respective protective members.

In addition, the carrier substrate may include a supporting layer, release layers disposed on both surfaces of the supporting layer, respectively, and adhesive layers disposed on each release layer.

Also, in the separating the semiconductor package from the carrier substrate, the adhesive layer, which is separated from the release layer, contacts the active element and is disposed on the lower surface of the semiconductor package such that it can be used as a heat dissipation member.

Also, the separating the semiconductor package from the carrier substrate, may include removing the adhesive layer that is separated from the release layer, contacts the active element, and is disposed on the lower surface of the semiconductor package.

Also, the method of manufacturing the semiconductor package may further include, after the separating the semiconductor package, attaching the heat dissipation member on the active element exposed by the penetration part.

Also, the adhesive layer may include a metal thin film or an insulating film.

Further, the buildup layer may be formed in a multi-layer and vias, which are provided on each buildup layer and perform interlayer connection, may be formed to be stacked in a row.

In addition, the forming the semiconductor packages on both surfaces of the carrier substrate may further include forming a solder resist layer on the buildup layer

The semiconductor package of the present invention is formed as the coreless package substrate without the core, making it possible to reduce the thickness of the package substrate and improve the signal transmission speed of the semiconductor package.

In addition, the semiconductor package of the present invention can improve the problem of the bending of the package substrate occurring during the manufacturing process and the productivity of the semiconductor package.

Moreover, the semiconductor package of the present invention has the passive element and the active element therein, making it possible to improve the rigidity of the semiconductor package.

Also, the protective member is provided on the lower part of the semiconductor package to protect the passive element that can be exposed to the outside, making it possible to secure the reliability of the semiconductor package.

Further, the adhesive layer, which is a part of the carrier substrate for manufacturing the semiconductor package, can be used as the protective member or the heat dissipation member of the semiconductor package, making it possible to simplify the process and reduce the process cost.

### BRIEF DESCRIPTION OF THE DRAWINGS

FIG. 1 is a cross-sectional view of a semiconductor package according to a first embodiment of the present invention;

FIGS. 2 to 9 are cross-sectional views for explaining a method of manufacturing a semiconductor package according to a first embodiment of the present invention;

FIG. 10 is a cross-sectional view of a semiconductor package according to a second embodiment of the present invention;

FIGS. 11 to 12 are cross-sectional views for explaining the method of manufacturing the semiconductor package according to the second embodiment of the present invention;

FIG. 13 is a cross-sectional view of a semiconductor package according to a third embodiment of the present invention;

FIGS. 14 to 16 are cross-sectional views for explaining the method of manufacturing the semiconductor package according to the third embodiment of the present invention;

FIG. 17 is a cross-sectional view of a semiconductor package according to a fourth embodiment of the present invention; and

FIGS. 18 to 20 are cross-sectional views for explaining the method of manufacturing the semiconductor package according to the fourth embodiment of the present invention.

### DETAILED DESCRIPTION OF THE PREFERRED EMBODIMENTS

Hereinafter, a semiconductor package according to embodiments of the present invention will be described in detail with reference to the accompanying drawings. The embodiments of the present invention to be described below are provided so that those skilled in the art to which the present invention pertains can fully carry out the present invention. Therefore, the present invention may be modified in many different forms and it should not be limited to the embodiments set forth herein. In the drawings, the thickness and the size of the device may be exaggerated for the convenience. Like reference numerals designate like components throughout the specification.

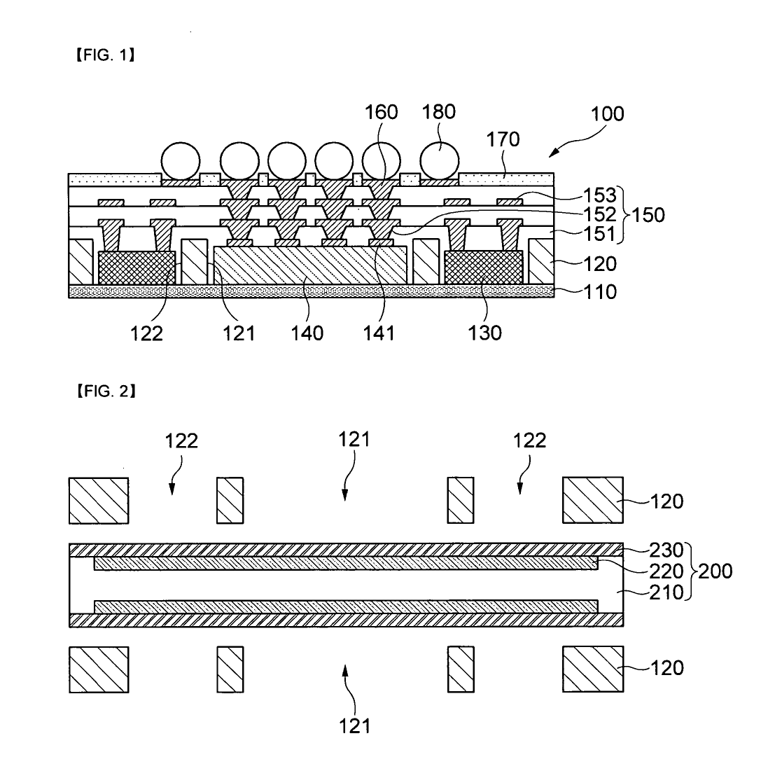

FIG. 1 is a cross-sectional view of a semiconductor package according to a first embodiment of the present invention.

Referring to FIG. 1, a semiconductor package 100 according to a first embodiment of the present invention may include a protective member 110, insulators 120, an active element 140, passive elements 130, a buildup layer 150, and an external connection unit 180.

The protective member 110 may be made of an insulating material. For example, the protective member 110 may be made of a solder resist.

The insulator 120 is disposed on the protective member 110. The insulator 120 may be made of insulating materials, for example, PPG (Prepreg) or ABF(Ajimonoto buildup film). The insulator 120 may include first and second opening parts 121 and 122 that are penetrated. Herein, the protective member 110 may be exposed from the insulator 120 through the first opening part 121 and the second opening part 122.

The active element 140 may be disposed on the protective member 110 exposed by the first opening part 121. In other words, the protective member 110 may be formed to cover a lower surface of the active element 140. Thereby, a lower surface of the insulator 120 and a lower surface of the active element 140 may be disposed on a straight line. Further, although an example of the active element 140 may include a diode and a transistor, etc., as a semiconductor device, the embodiment of the present invention is not limited thereto. In addition to this, a contact pad 141 to be described below, which is electrically connected to the buildup layer 150, may be disposed on an upper part of the active element 140.

The passive element 130 may be disposed on the protective member 110 exposed by the second opening part 122. In other words, the protective member 110 may be formed to cover the lower surface of the passive element 130 such that the passive element 130 can be protected from the external environment. Further, although an example of the passive element 130 may include an MLCC, a resistor, and an inductor, etc., the embodiment of the present invention is not limited thereto.

In addition to this, although not shown in the drawings, the insulator 120 may have circuits therein. Herein, the circuits may be electrically connected to the passive element 130. At this time, a part of the circuits may be exposed on the lower part of the insulator 120. At this time, the protective member 110 covers the exposed circuits such that the exposed circuits can be protected from the external environment.

The buildup layer 150 is disposed on the insulator 120 including the active element 140. At this time, the buildup layer 150 may perform a role of electrically connecting the active element 140 and an external circuit part, for example, a main board substrate to each other.

The buildup layer 150 may include an insulating layer 151, vias 152 that penetrate the insulating layer 151 and perform interlayer connection, and a circuit layer 153 that is electrically connected to the vias and is disposed on the insulating layer 151. Herein, the buildup layer 150 may be formed in a multi-layer of at least one layer. At this time, the vias 152, which perform the interlayer connection of the buildup layer 150 of a multi-layer, may be formed to be stacked in a row. Therefore, an electrical passage from the active element to the main board substrates that are the external circuit parts can be shortened and as they are directly and electrically connected without a separate connection unit, for example, a bump, a signal transmission speed between the active element and the main board substrate can be increased.

In addition to this, the buildup layer of the uppermost layer in the buildup layer 150 of a multi-layer may include a pad 160 for electrically connecting to the main board substrate.

In addition, a solder resist layer 170 exposing the pad 160 is disposed on the buildup layer 150, making it possible to protect the circuit layer of the outermost layer from the outside and to prevent a short defect between the pad 160 and an external connection unit 180 to be described below.

Also, the external connection unit 180, for example, a solder ball, which is electrically connected to a pad 144 exposed from the solder resist layer 170, is disposed. Herein, the semiconductor package and the main board substrate may be electrically connected to each other by the external connection unit 180.

According to the embodiment of the present invention, the semiconductor package is the coreless package substrate that does not have a core, such that the thickness of the package substrate can reduce and the signal transmission speed can increase.

In addition, the semiconductor package can more increase the signal transmission speed as the vias for the interlayer connection are stacked in a row.

Moreover, the semiconductor package has the passive element and the active element inside the package substrate, making it possible to improve the rigidity of the semiconductor package.

Also, the protective member is provided on the lower part of the semiconductor package to protect the circuit or the passive element that can be exposed to the outside, making it possible to secure the reliability of the semiconductor package.

Hereinafter, a method of manufacturing the semiconductor package according to a first embodiment of the present invention will be described in more detail with reference to FIGS. 2 to 9.

FIGS. 2 to 9 are cross-sectional views for explaining a method of manufacturing a semiconductor package according to a first embodiment of the present invention.

Referring to FIG. 2, in order to manufacture the semiconductor package according to the first embodiment of the present invention, insulators 120 are first provided on both surfaces of a carrier substrate 200, respectively.

The carrier substrate 200 may include a supporting layer 210, release layers 220 that are disposed on both surfaces of the supporting layer 210, respectively, and adhesive layers 230 that are disposed on each release layer 220.

The supporting layer 210 may be made of a material that can support a body of the carrier substrate 200, for example, plastic or metal.

The release layers 220 may be disposed on both surfaces of the supporting layer 210, respectively. The release layer 220 may be formed of a release film as a material that can easily be separated from the adhesive layer 230. Herein, the release layer 220 may expose an edge of the supporting layer 210 and may be disposed on the supporting layer 210.

The adhesive layers 230 may be disposed on both surfaces of the supporting layer 210 including the release layers 220, respectively. The adhesive layer 230 may be disposed to completely cover the supporting layer 210 and may be disposed on the edge of the supporting layer 210 exposed from the release layer 220.

The adhesive layer may be formed of an insulating film or a metal thin film, for example, a copper thin film.

In order to separate the release layer 220 from the adhesive layer, adhesive strength between the release layer 220 and the supporting layer 210 may be larger than adhesive strength between the release layer 220 and the adhesive layer 230. At this time, the release layer 220 may be fixed to the carrier substrate 200 due to the adhesion between the edge of the supporting layer and the adhesive layer 230. Thereby, when the edge of the supporting layer is cut, it is possible to separate the adhesive layer 230 from the release layer 220.

The insulator 120 may include the first and second opening parts 121 and 122 that penetrate through the body. Herein, the first and second opening parts 121 and 122 of the insulator 120 may be formed by general processing, for example, punching processing, laser processing, and water-jet processing, etc.

Further, an example of a material used as the insulator 120 may include PPG(Prepreg) or ABF(Ajimonoto buildup film).

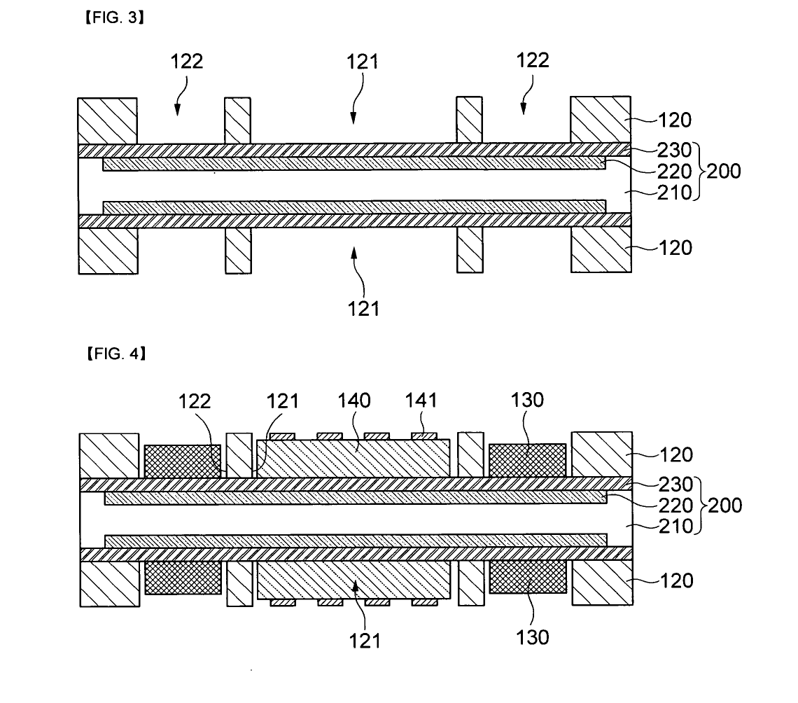

Referring to FIG. 3, the insulators 120 are stacked on both surfaces of the carrier substrate 200, respectively. At this time, the opening part 121 of the insulating pattern 120 may expose the carrier substrate 200, in particular, the adhesive layer 230.

Referring to FIG. 4, the active elements 140 are mounted on both surfaces of the carrier substrate 200, respectively, that is exposed from the insulator 120, that is, corresponds to the first opening unit 121. Herein, the mounting of the active element 140 may be performed by the adhesive layers each applied on both surfaces of the carrier substrate 200, respectively. At this time, the contact pads 141 may be disposed on the upper surface of the active element 140, respectively. Although an example of the active element 140 may include a diode and a transistor, etc., the embodiment of the present invention is not limited thereto.

The passive elements 130 are mounted on both surfaces of the carrier substrate 200, respectively, that corresponds to the second opening unit 122 together with the mounting of the active element 140. As an example of the passive element 130, the MLCC, the resistor, and the inductor may be included therein and in the embodiment of the present invention, the kind of the passive element 130 is not limited thereto.

In addition to this, the insulator 120 may have a circuit therein.

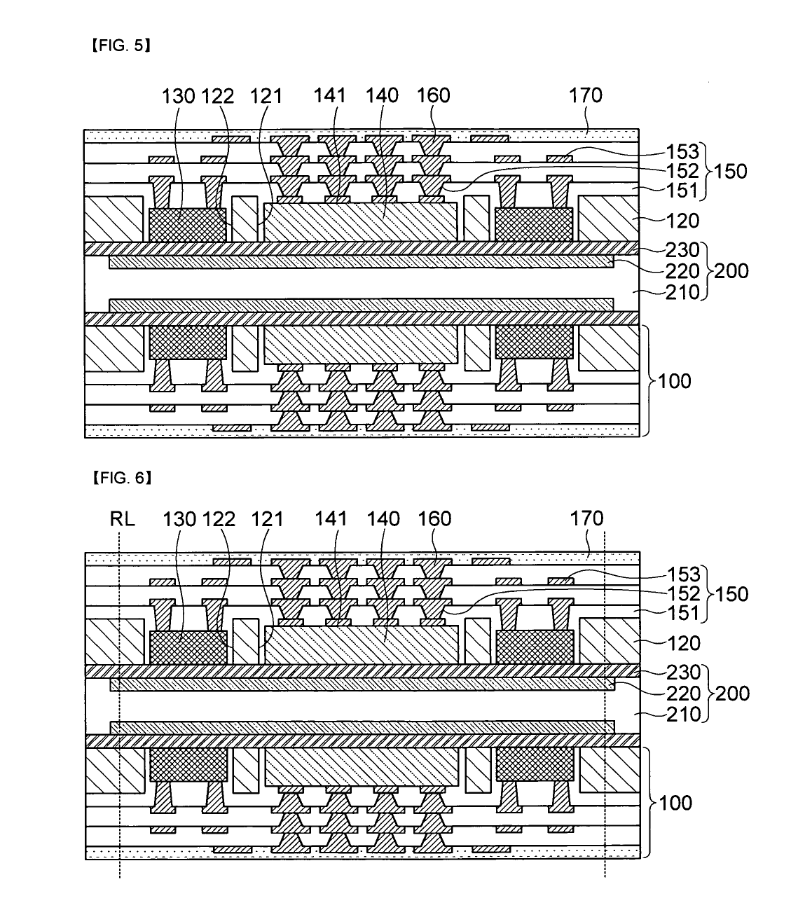

Referring to FIG. 5, the buildup layers 150 of at least one layer, which is electrically connected to the active elements 140, are formed on both surfaces of the carrier substrate 200 including the active element 140, respectively.

In order to form the buildup layer 150, the insulating layers 151 are formed on both surfaces of the carrier substrate 200 including the active element 140, respectively. Herein, an example of a material forming the insulating layer 151 may be an epoxy resin. However, in the embodiment of the present invention, the material of the insulating layer 151 is not limited thereto.

Thereafter, a via hole, which exposes the contact pad 141 of the active element 140, is formed on the insulating layer 151 using laser processing or CNC, drill, or photolithography processes.

Thereafter, an electroless plating and an electrolysis plating are performed on each insulating layer 151 to form a copper foil and a via 152 and a circuit layer 153 electrically connected to the contact pad 141 can then be formed by etching the copper foil. Thereby, the buildup layers 150, which includes the insulating layer 151 and the via 152 and the circuit layer 153 penetrating through the insulating layer 151 and electrically connected to the contact pad 141, can be formed on both surfaces of the carrier substrate 200, respectively.

Although the embodiment of the present invention described that the via 151 is formed by a process of forming the electroless plating and the electrolysis plating, the embodiment is not limited thereto. The via 151 may be formed by filling a conductive paste in the via hole.

Herein, the buildup layers 150 of a multi-layer may be formed on both surfaces of the carrier substrate 200, respectively, by repetitively forming the buildup layer 150.

At this time, the vias 151 included in each buildup layer may be stacked to be disposed in a row. Thereby, the electrical passage for the interlayer connection within the package substrate may be reduced, making it possible to reduce the signal transmission speed of the semiconductor package. This can be achieved because the package substrate is the coreless substrate. In other words, the package substrate including the conventional core includes a plated through hole (PTH), through which the core penetrates, for the interlayer connection. Consequently, the package substrate of the related art includes the PTH between the vias stacked for the interlayer connection, such that only the vias for the interlayer connection cannot be stacked in a row as in the present invention.

Further, as each buildup layer 150 is formed on both surfaces of the carrier substrate 200, the shrinkage occurring in the buildup process of forming the buildup layer 150 occurs in conflict with each other at both surfaces of the carrier substrate 200, such that the bending of the package substrate can be prevented in the buildup process.

In addition to this, the buildup layer of the uppermost layer in the buildup layer 150 of a multi-layer may be provided with the pad 160 for electrically connecting to the main board substrate.

Thereafter, the solder resist layer 170 covering each buildup layer 150 including the pad can be formed.

Thereby, the semiconductor packages 100, which include the insulator 120 including the active element 140 and the buildup layer 150 disposed on the insulator 120, can be formed on both surfaces of the carrier substrate 200, respectively.

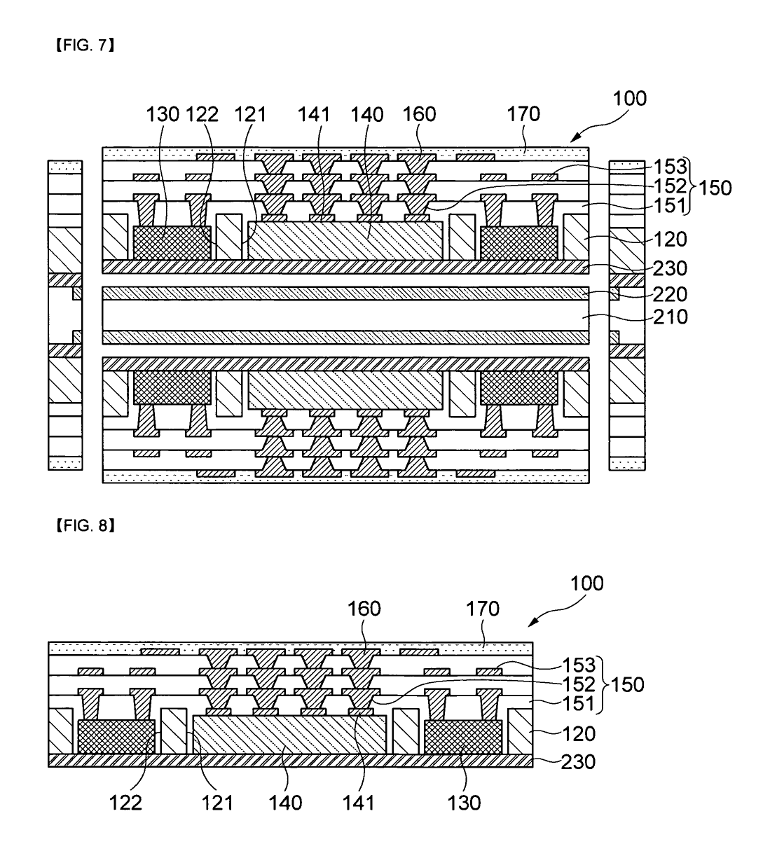

Referring to FIG. 6, a routing process is performed on the carrier substrate 200 along a routing line (RL) of the carrier substrate 200 as shown in FIG. 7. Herein, the edge portions of the carrier substrate 200, that is, the adhesive layer 230 and the supporting layer 210, which are adhered to each other, are cut in the routing process, making it possible to naturally separate the release layer 220 and the adhesive layer 230. Thereby, it is possible to easily separate the semiconductor package 100 from the carrier substrate 200.

Referring to FIG. 8, the adhesive layer 230 may remain in the lower part of the semiconductor package 100 that is separated from the carrier substrate 200. Herein, when the adhesive layer 230 is formed of the insulating film, the adhesive layer 230 remains, which can be used as the protective member 110.

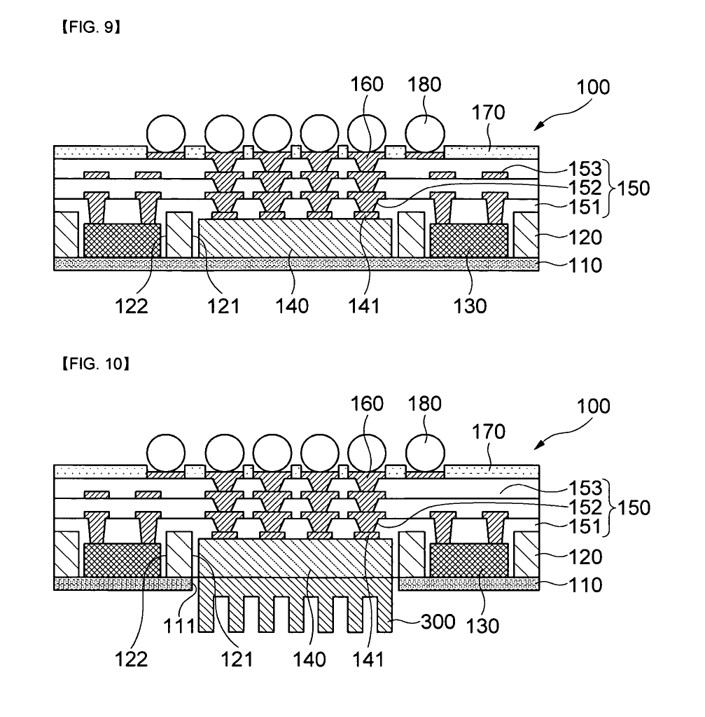

However, when the adhesive layer 230 is formed of a metal thin film, the adhesive layer 230 can be removed and the protective member 110 made of an insulating material can then be separately formed on the lower part of the semiconductor package 100 as shown in FIG. 9. Herein, the protective member 110 may be formed by applying the solder resist.

Thereby, the protective member 110 can protect the circuit or the lower surface of the passive element that can be exposed to the outside.

Thereafter, the exposure and development processes are performed on the solder resist layer 170, thereby exposing the pad 160 of the semiconductor package 100. Thereafter, the external connection unit 180, for example, the solder ball, which is electrically connected to the pad 160 and is connected to the external circuit unit, for example, the main board substrate, is formed in the semiconductor package 100.

Therefore, as the semiconductor package is formed on each side surface of the carrier substrate, respectively, as in the first embodiment of the present invention, the bending of the semiconductor substrate that can occur during the formation process can be prevented.

In addition, at least two semiconductor packages can be manufactured through one-time process, making it possible to improve the productivity of the semiconductor package.

Hereinafter, a semiconductor package according to a second embodiment of the present invention will be described with reference to FIG. 10. Herein, the semiconductor package according to the second embodiment has the same configuration as the semiconductor package according to the above-mentioned first embodiment except for a protective member and a heat dissipation member. Therefore, the description of the same components as the first embodiment will not be repeated in the second embodiment.

FIG. 10 is a cross-sectional view of a semiconductor package according to a second embodiment of the present invention.

Referring to FIG. 10, a semiconductor package according to a second embodiment of the present invention may include the insulator 120 that has the first and second opening parts 121 and 122, the active element 140 that is disposed inside the first opening part 121, the passive element 130 that is disposed inside the second opening part 122, the protective member 110 that covers the lower part of the passive element 130 and is disposed on the lower part of the insulator 120, the buildup layer 150 that is disposed on the insulator 120 and is electrically connected to the active element 140, and the external connection unit 180 that is electrically connected to the buildup layer 150.

Herein, the protective member 110 may include a penetration part 111 that corresponds to the first opening part 121 of the insulator 120. Thereby, the lower surface of the active element 140 may be exposed to the outside by the penetration part 111. As a result, heat generated from the active element may be discharged to the outside.

In addition to this, a heat dissipation member 300 may be attached to the lower part of the active element 140 exposed by the penetration part 111. The heat dissipation member 300 more efficiently discharges heat generated from the active element 140 to the outside, making it possible to secure the reliability of the semiconductor package.

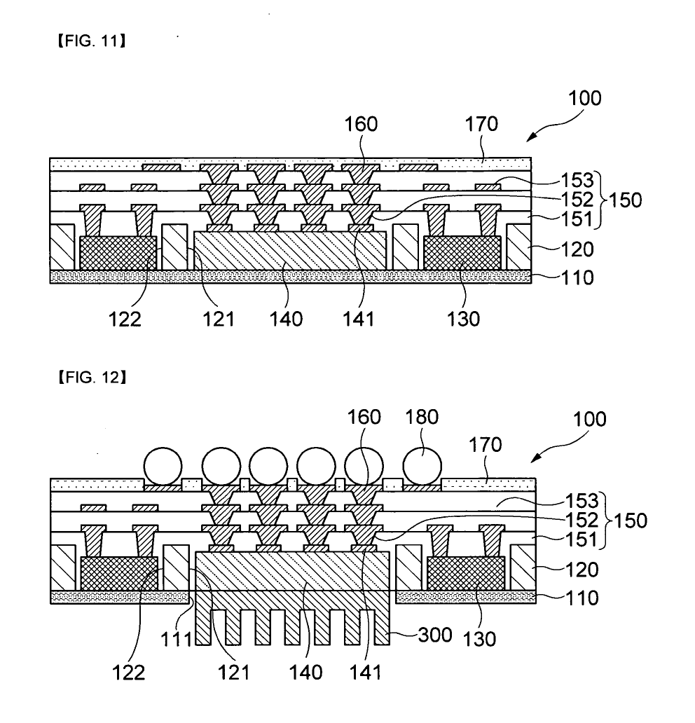

Hereinafter, a method of manufacturing the semiconductor package according to the second embodiment of the present invention will be described in more detail with reference to FIGS. 11 to 12. Herein, the semiconductor package is manufactured by the method of manufacturing the semiconductor package according to the above-mentioned first embodiment except for forming the protective member and the heat dissipation member and therefore, the description of the same manufacturing processes as the first embodiment will not be repeated in the second embodiment.

FIGS. 11 to 12 are cross-sectional views for explaining the method of manufacturing the semiconductor package according to the second embodiment of the present invention.

Referring to FIG. 11, the semiconductor packages 100 are manufactured on both surfaces of the carrier substrate (200 of FIG. 2), respectively and the semiconductor package 100 is then separated from the carrier substrate 200.

Thereafter, the protective member 110 is formed on the lower part of the semiconductor package 100. Herein, the protective member 100 may be used as the adhesive layer (230 of FIG. 2) of the carrier substrate 200 that remains in the lower part of the semiconductor package 100 during the process of separating the semiconductor package 100 from the carrier substrate 200.

Alternately, after removing the adhesive layer 230, the protective member 110 may separately be formed on the lower part of the semiconductor package 100.

Referring to FIG. 12, the exposure and development processes are performed on the solder resist layer 170 that is disposed on the semiconductor package 100, thereby exposing the pad 160 of the semiconductor package 100. Thereafter, the external connection unit 180, for example, the solder ball, which is electrically connected to the pad 160 and is connected to the external circuit unit, for example, the main board substrate, is formed in the semiconductor package 100.

Then, the exposure and development processes are performed on the protective member 110, making it possible to form the penetration part 111 exposing the lower surface of the active element 140. Thereby, the active element 140 is exposed to the outside, making it possible to effectively discharge heat generated from the active element 140 to the outside.

In addition to this, a separate heat dissipation member 300 may be further attached to the lower surface of the exposed active element 140. Thereby, the semiconductor package 100 can more effectively discharge heat from the active element 140.

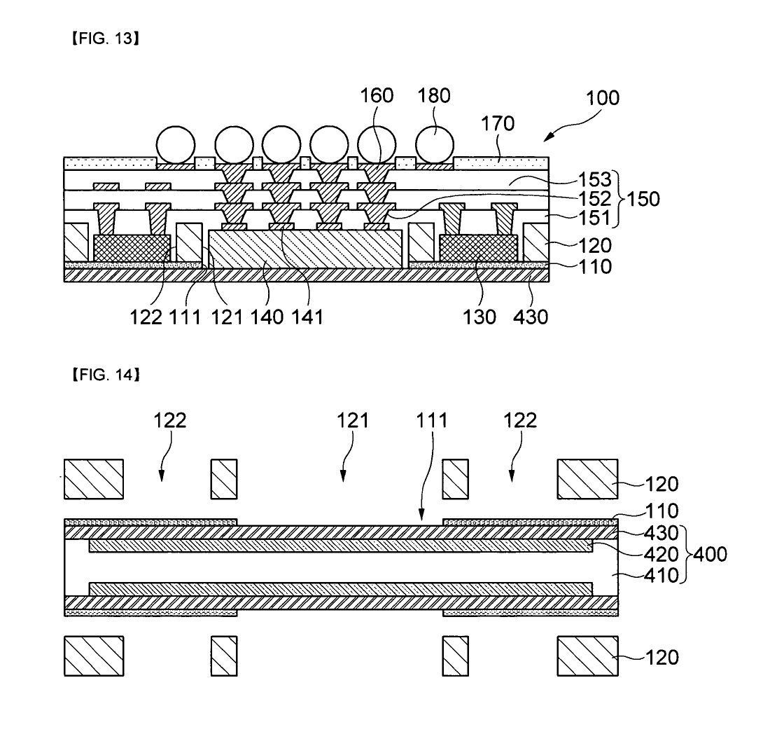

Hereinafter, a semiconductor package according to a third embodiment of the present invention will be described with reference to FIG. 13. Herein, the semiconductor package according to the third embodiment has the same configuration as the semiconductor package according to the above-mentioned first embodiment except for a protective member. Therefore, the description of the same components as the first embodiment will not be repeated in the third embodiment.

FIG. 13 is a cross-sectional view of a semiconductor package according to a third embodiment of the present invention.

Referring to FIG. 13, a semiconductor package according to a third embodiment of the present invention may include the insulator 120 that has the first and second opening parts 121 and 122, the active element 140 that is disposed inside the first opening part 121, the passive element 130 that is disposed inside the second opening part 122, the protective member 110 that covers the lower part of the passive element 130 and is disposed on the lower part of the insulator 120, the buildup layer 150 that is disposed on the insulator 120 and is electrically connected to the active element 140, and the external connection unit 180 that is electrically connected to the buildup layer 150.

Herein, the protective member 100 may include the penetration part 111 penetrating through the body. At this time, the penetration unit 111 may be disposed to correspond to the first opening part 121. Therefore, the lower part of the active element 140 may be exposed to the outside by the penetration part 111.

Further, an etching surface 112 of the penetration part 111 may be disposed on the side surface of the active element 140. Thereby, the lower surface of the protective member 110 and the lower surface of the active element 140 may be disposed on a straight line. In the manufacturing process, this is because a subsequent process of stacking the protective members 110 including the penetration part 111 and the insulators 120 including the first and second opening part 121 and 122 on both surfaces of the carrier substrate, respectively and then mounting the active elements is performed. This will be described in detail below.

In addition to this, the semiconductor package 100 may further include an adhesive layer 430 that contacts the active element 140 exposed by the penetration part 111. Herein, the adhesive layer 430 can perform a role of the heat dissipation member that discharges heat generated from the active element 140 to the outside. At this time, the adhesive layer 430, that is, the heat dissipation member may be disposed to be extended to the lower surface of the protective member 110.

Hereinafter, a method of manufacturing a semiconductor package according to the third embodiment of the present invention will be described in more detail with reference to FIGS. 14 to 16. Herein, the semiconductor package is manufactured by the method of manufacturing the semiconductor package according to the above-mentioned first embodiment except for forming the protective member and therefore, the description of the same manufacturing processes of the semiconductor package as the first embodiment will not be repeated in the third embodiment.

FIGS. 14 to 16 are cross-sectional views for explaining the method of manufacturing the semiconductor package according to the third embodiment of the present invention.

Referring to FIG. 14, the protective members 110 and the insulators 120 are stacked on both surfaces of the carrier substrate 400, respectively. Herein, the carrier substrate 400 may include a supporting layer 410, release layers 420 that are disposed on both surfaces of the supporting layer 410, respectively, and adhesive layer 430 that are disposed on each release layer 420.

The protective members 110 including the penetration parts 111 are formed on both surfaces of the carrier substrate 400. Herein, in order to form the protective member 110, the protective layer are formed on both surfaces of the carrier substrate 400 and the protective layers are then subjected to the exposure and development processes, making it possible to form the penetration part 111. At this time, an example of a material forming the protective layer may include a solder resist. As another example of forming the protective member 110, the protective member is subjected to general processing, for example, punching processing, laser processing, and water-jet processing to form the penetration parts, which can be in turn stacked on both surfaces of the carrier substrate 400.

Thereafter, the insulators 120 having the first and second opening parts 121 and 122 are stacked on each protective member 110. At this time, the insulator 120 is stacked on the protective member 110 so that the first opening part 121 and the penetration unit 111 correspond to each other. Thereby, the carrier substrate 400 may be exposed to the outside by the first opening part 121 and the penetration part 111. Meanwhile, the protective member 110 may be exposed to the outside by the second opening part 122.

Herein, the first and second opening parts 121 and 122 of the insulator 120 may be formed by the general processing, for example, the punching processing, the laser processing, and the water-jet processing, etc. Further, an example of a material used as the insulator 120 may include PPG(Prepreg) or ABF(Ajimonoto buildup film).

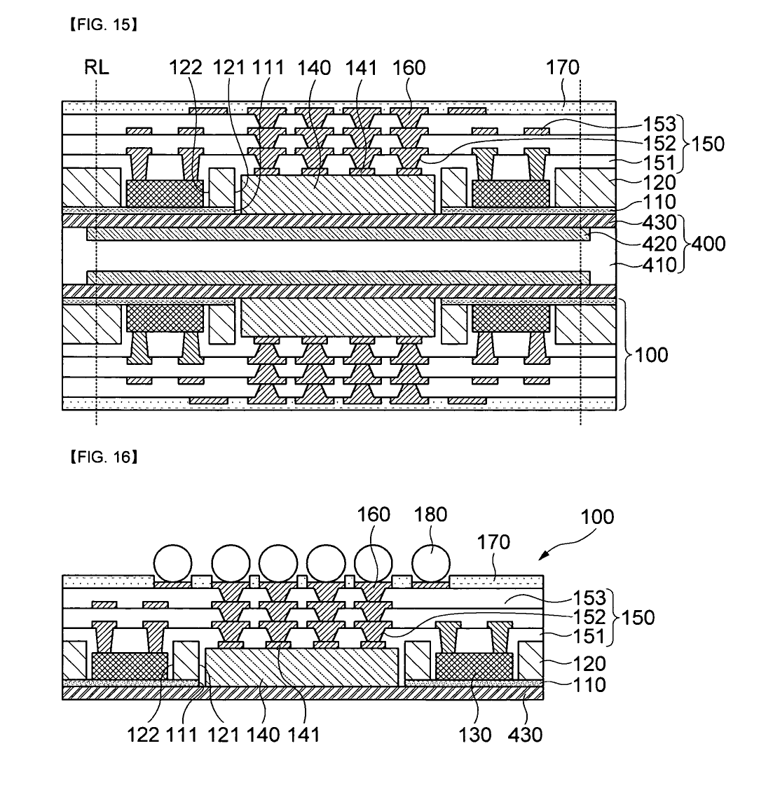

Referring to FIG. 15, the active elements 140 are mounted on both surfaces of the carrier substrate 400 exposed by the first opening part 121 and the penetration part 111, respectively. In addition, the passive element 130 is mounted on the protective member 110 exposed by the second opening part 121.

Thereafter, the buildup layer 150, which is electrically connected to the active element 140, is formed on the insulator 120.

Then, after the solder resist layer 170 is formed on the buildup layer 150, the edge of the carrier substrate 400 is cut along the routing line (RL), making it possible to separate the semiconductor package 100 from the carrier substrate 400 as in FIG. 16. At this time, the adhesive layer 430 of the carrier substrate 400 may remain on the lower surface of the semiconductor package 100. The adhesive layer 431 contacts the active element 140 exposed by the penetration part 111 and may be disposed on the lower surface of the protective member 110. Herein, the adhesive layer 430 of the carrier substrate 400 may be formed of a metal thin film having large thermal conductivity, for example, a Cu foil. As a result, the adhesive layer 430 remaining on the lower part of the semiconductor package 100 may perform a role of the heat dissipation member that discharges heat generated from the active element 140 to the outside.

Thereafter, after the solder resist layer 170 is subjected to the exposure and development processes to expose the pad 160 of the semiconductor package 100, the external connection unit 180, for example, the solder ball, which is electrically connected to the pad 160 and is connected to the external circuit unit, for example, the main board substrate, is formed in the semiconductor package 100.

Therefore, the adhesive layer, which is a part of the carrier substrate for forming the semiconductor package in the embodiment of the present invention, can be used as the heat dissipation member of the semiconductor package, making it possible to simplify the process and reduce the process cost.

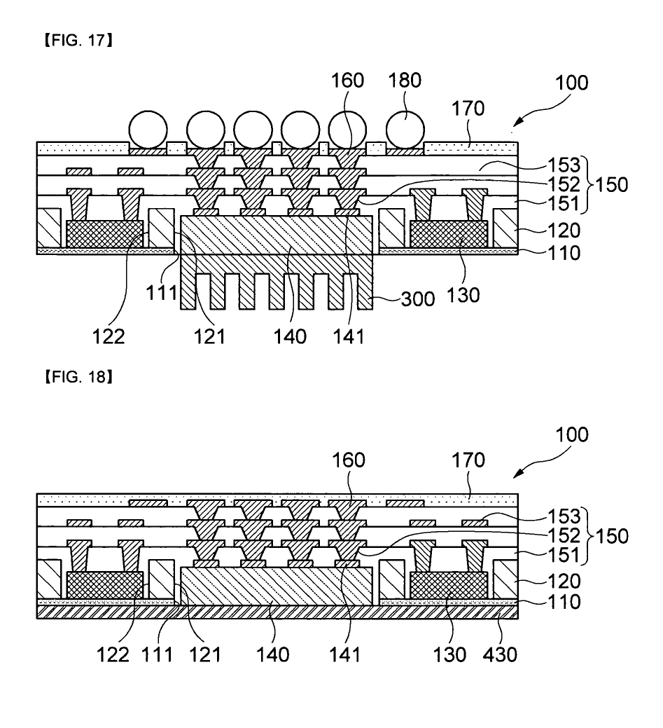

Hereinafter, a semiconductor package according to a fourth embodiment of the present invention will be described with reference to FIG. 17. Herein, the semiconductor package according to the fourth embodiment has the same configuration as the semiconductor package according to the above-mentioned second embodiment except for a protective member. Therefore, the description of the same components as the second embodiment will not be repeated in the fourth embodiment.

FIG. 17 is a cross-sectional view of a semiconductor package according to a fourth embodiment of the present invention.

Referring to FIG. 17, a semiconductor package according to a fourth embodiment of the present invention may include the insulator 120 that has the first and second opening parts 121 and 122, the active element 140 that is disposed inside the first opening part 121, the passive element 130 that is disposed inside the second opening part 122, the protective member 110 that covers the lower part of the passive element 130 and is disposed on the lower part of the insulator 120, the buildup layer 150 that is disposed on the insulator 120 and is electrically connected to the active element 140, and the external connection unit 180 that is electrically connected to the buildup layer 150.

Herein, the protective member 110 may include the penetration part 111 that is extended to the first opening part 121. At this time, the lower surface of the active element 140 may be exposed by the penetration part 111, such that the active element 140 can effectively discharge heat to the outside.

In addition to this, the heat dissipation member is attached to the lower part of the active element 140 exposed to the outside, such that heat generated from the active element can be effectively discharged to the outside.

Hereinafter, a method of manufacturing a semiconductor package according to the fourth embodiment of the present invention will be described in more detail with reference to FIGS. 18 to 20. Herein, the semiconductor package is manufactured by the method of manufacturing the semiconductor package according to the above-mentioned second embodiment except for forming the protective member and therefore, the description of the same manufacturing processes of the semiconductor package as the second embodiment will not be repeated in the fourth embodiment.

FIGS. 18 to 20 are cross-sectional views for explaining the method of manufacturing the semiconductor package according to the fourth embodiment of the present invention.

Referring to FIG. 18, each of the semiconductor packages 100 is manufactured on both surfaces of the carrier substrate (400 of FIG. 14) and the semiconductor package 100 is then separated from the carrier substrate 400.

Herein, the adhesive layer (430 of FIG. 14) of the carrier substrate 400 may remain in the lower part of the semiconductor package 100 during the process of separating the semiconductor package 100 from the carrier substrate 200. At this time, the adhesive layer 430 may be formed of an insulating film or a metal thin film.

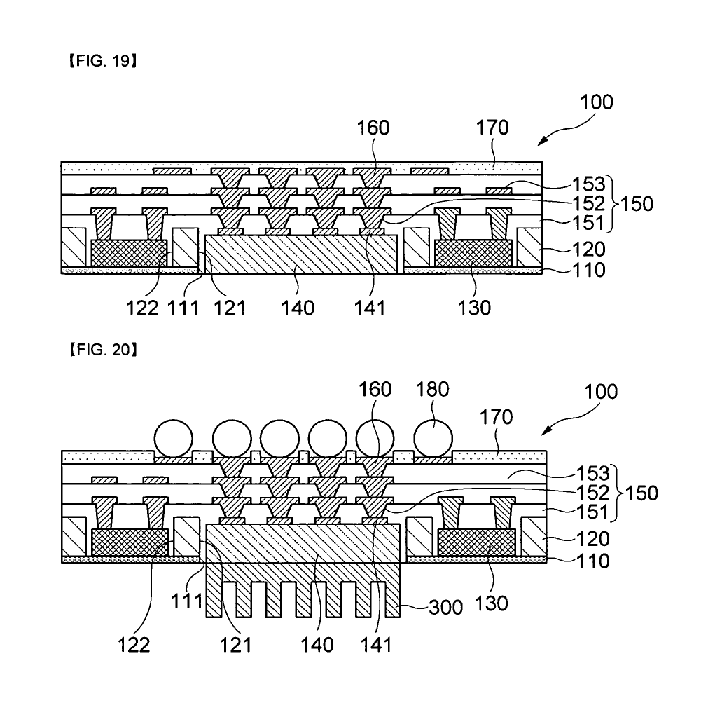

Referring to FIG. 19, the adhesive layer 430 is removed from the semiconductor package 100. Herein, the adhesive layer 430 may be removed through a wet process or a dry process. At this time, the protective member 110 may perform a role of protecting the circuit or the passive element 130 exposed from the insulator 120 during the process of removing the adhesive layer 430.

Referring to FIG. 20, the solder resist layer 170, which is disposed on the semiconductor package 100, is subject to the exposure and development processes, thereby exposing the pad 160 of the semiconductor package 100. Thereafter, the external connection unit 180, for example, the solder ball, which is electrically connected to the pad 160 and is connected to the external circuit unit, for example, the main board substrate, is formed in the semiconductor package 100

Thereafter, the heat dissipation member 300 is attached to the lower surface of the semiconductor package 100, that is, the lower surface of the active element, making it possible to form the semiconductor package having the heat dissipation effect.

Therefore, in the embodiment of the present invention, the semiconductor packages are manufactured on both surface of the carrier substrate, respectively, making it possible to improve the problem of the bending of the package substrate that may occur during the process of forming the semiconductor package.

Further, the semiconductor package is manufactured on both surfaces of the carrier substrate, respectively, such that at least two semiconductor packages can be manufactured through one-time process, making it possible to improve the productivity of the semiconductor package.

In addition, the semiconductor package is manufactured using the carrier substrate, such that the package substrate does not need the core, making it possible to reduce the thickness of the semiconductor package and improve the signal transmission speed of the semiconductor package.

Moreover, the semiconductor package of the present invention has the passive element and the active element therein, making it possible to improve the rigidity of the semiconductor package.

Also, the protective member is provided on the lower part of the semiconductor package to protect the passive element that can be exposed to the outside, making it possible to secure the reliability of the semiconductor package.

Further, the adhesive layer, which is a part of the carrier substrate for manufacturing the semiconductor package, can be used as the protective member or the heat dissipation member of the semiconductor package, making it possible to simplify the process and reduce the process cost.

What is claimed is:

1. A semiconductor package comprising:
insulators that have first and second opening parts;
an active element that is disposed inside the first opening part;
a passive element that is disposed inside the second opening part;
a protective member that is disposed on a lower part of the insulator and covers a lower part of the passive element;
a buildup layer that is disposed on the insulator and is electrically connected to the active element; and
an external connection unit that is electrically connected to the buildup layer.

2. The semiconductor package according to claim 1, wherein the protective member covers a lower surface of the active element.

3. The semiconductor package according to claim 1, wherein the protective member includes a penetration part is disposed to correspond to the first opening part and expose the lower surface of the active element.

4. The semiconductor package according to claim 3, further comprising a heat dissipation member that is attached to the lower surface of the active element.

5. The semiconductor package according to claim 3, further comprising a heat dissipation member that is disposed on the lower surface of the protective member including the lower surface of the active element.

6. The semiconductor package according to claim 3, wherein an etching surface of the protective member for forming the penetration part faces a side surface of the active element.

7. The semiconductor package according to claim 1, wherein the lower surface of the insulator and the lower surface of the active element is disposed on a straight line.

8. The semiconductor package according to claim 1, wherein the buildup layer is formed in a multi-layer and vias, which are provided on each buildup layer and perform interlayer connection, are stacked in a row.

9. A method of manufacturing a semiconductor package, comprising:
providing a carrier substrate;
stacking insulators including first and second opening parts on both surfaces of the carrier substrate, respectively;
forming each of the semiconductor packages that include active elements disposed on both surfaces of the carrier substrate corresponding to the first opening part, passive elements disposed on both surfaces of the carrier substrate corresponding to the second opening part, and a buildup layer of at least one layer electrically connected to the active element;
forming a protective member, which separates the semiconductor package from the carrier substrate, on a lower part of the semiconductor package including the passive element; and
forming an external connection unit on the semiconductor package.

10. The method of manufacturing a semiconductor package according to claim 9, wherein the carrier substrate includes a supporting layer, release layers disposed on both surfaces of the supporting layer, respectively, and adhesive layers disposed on the release layers.

11. The method of manufacturing a semiconductor package according to claim 10, wherein the forming the protective member on the lower part of the semiconductor package that separates the semiconductor package from the carrier substrate and includes the passive element includes:
removing the adhesive layer that is separated from the release layer and is disposed on the lower surface of the semiconductor package; and
forming a protective member on the lower surface of the semiconductor package.

12. The method of manufacturing a semiconductor package according to claim 10, wherein the forming the protective member, which separates the semiconductor package from the carrier substrate, on the lower part of the semiconductor package including the passive element is used as a protective member by leaving the adhesive layer that is separated from the release layer and is disposed on the lower surface of the semiconductor package.

13. The method of manufacturing a semiconductor package according to claim 10, wherein the adhesive layer includes a metal thin film or an insulating film.

14. The method of manufacturing a semiconductor package according to claim 10, further comprising a penetration part that exposes the lower surface of the active element.

15. The method of manufacturing a semiconductor package according to claim 14, further comprising attaching a heat dissipation member to the lower surface of the active element.

16. The method of manufacturing a semiconductor package according to claim 9, wherein the buildup layer is formed in a multi-layer and vias, which are provided on each buildup layer and perform interlayer connection, are formed to be stacked in a row.

17. The method of manufacturing a semiconductor package according to claim 9, wherein the forming the semiconductor packages on both surfaces of the carrier substrate, respectively, further includes forming a solder resist layer on the buildup layer

18. A method of manufacturing a semiconductor package, comprising:
providing a carrier substrate;
forming a protective member, which includes a penetration part, and insulators, which are disposed on the protective member and include first and second opening parts, on both surfaces of the carrier substrate;
forming each of the semiconductor packages that includes active elements disposed on both surfaces of the carrier substrate corresponding to the first opening part, passive elements disposed on both surfaces of the carrier substrate corresponding to the second opening part, and a buildup layer of at least one layer electrically connected to the active element;
separating the semiconductor package including the protective member from the carrier substrate; and
forming an external connection unit on the semiconductor package.

19. The method of manufacturing a semiconductor package according to claim 18, wherein the forming the insulator and the protective member includes:
forming the protective members including the penetration parts on both surfaces of the carrier substrate, respectively; and
stacking insulators including the first opening part corresponding to the penetration part and the second opening part disposed around the first opening part on the respective protective members.

20. The method of manufacturing a semiconductor package according to claim 18, wherein the carrier substrate includes a supporting layer, release layers disposed on both surfaces of the supporting layer, respectively, and adhesive layers disposed on each release layer.

21. The method of manufacturing a semiconductor package according to claim 20, wherein in the separating the semiconductor package from the carrier substrate, the adhesive layer, which is separated from the release layer, contacts the active element and is disposed on the lower surface of the semiconductor package such that it is used as a heat dissipation member.

22. The method of manufacturing a semiconductor package according to claim 20, wherein the separating the semiconductor package from the carrier substrate includes removing the adhesive layer that is separated from the release layer, contacts the active element, and is disposed on the lower surface of the semiconductor package.

23. The method of manufacturing a semiconductor package according to claim 22, further comprising after the separating the semiconductor package: attaching the heat dissipation member on the active element exposed by the penetration part.

24. The method of manufacturing a semiconductor package according to claim 20, wherein the adhesive layer includes a metal thin film or an insulating film.

25. The method of manufacturing a semiconductor package according to claim 18, wherein the buildup layer is formed in a multi-layer and vias, which are provided on each buildup layer and perform interlayer connection, are formed to be stacked in a row.

26. The method of manufacturing a semiconductor package according to claim 18, wherein the forming the semiconductor packages on both surfaces of the carrier substrate further includes forming a solder resist layer on the buildup layer
